(19) United States
(12) Patent Application Publication
(10) Pub. No.: US 2026/0059767 A1
(43) Pub. Date: Feb. 26, 2026

(54) SEMICONDUCTOR DEVICE

(71) Applicant: NANYA TECHNOLOGY CORPORATION, New Taipei City (TW)

(72) Inventor: Wei-Chuan FANG, New Taipei City (TW)

(21) Appl. No.: 18/814,577

(22) Filed: Aug. 25, 2024

(51) Int. Cl. H10B 63/10; H10N 70/00; H10N 70/20

(52) U.S. Cl. CPC H10B 63/10; H10N 70/231; H10N 70/841

(57) ABSTRACT

The present disclosure provides a semiconductor device. The semiconductor device includes a bottom electrode, a top electrode, and a phase-change memory structure. The bottom electrode includes graphene. The top electrode is disposed on the bottom electrode. The phase-change memory structure is disposed between the top electrode and the bottom electrode.

### BACKGROUND

### Field of Invention

The present disclosure relates to a semiconductor device.

### Description of Related Art

Phase-change memory (PCM) is a non-volatile memory technology that utilizes the unique properties of chalcogenide glass to store data. Phase-change memory operates by switching the phase of the chalcogenide material between its amorphous and crystalline states. The amorphous state has high electrical resistance, while the crystalline state has low resistance, enabling binary data storage. Phase-change memory is known for its high endurance, fast read/write speeds, and scalability, making it a promising alternative to traditional flash memory. However, challenges such as high power consumption and low charge transfer speed have influenced its integration into mainstream memory solutions.

### SUMMARY

According to some embodiments of the present disclosure, a semiconductor device includes a bottom electrode, a top electrode, and a phase-change memory structure. The bottom electrode includes graphene. The top electrode is disposed on the bottom electrode. The phase-change memory structure is disposed between the top electrode and the bottom electrode.

In some embodiments of the present disclosure, the top electrode includes graphene.

In some embodiments of the present disclosure, each of the bottom electrode and the top electrode includes N-doped graphene.

In some embodiments of the present disclosure, the phase-change memory structure includes GeSbTe, SiGeSb, Sb₂Te₃, GeTe, Cr₂Ge₂Te₆, VO₂, MoO₂, V₂O₃, NbO₂, Fe₃O₄, FeS, Ta₂O₅, Ti₃O₅, Ti₂O₃, LaCoO₃, SmNiO₃, or combinations thereof.

In some embodiments of the present disclosure, a length extending from the top electrode to the bottom electrode of the phase-change memory structure is 100 nm to 200 nm.

In some embodiments of the present disclosure, a width extending parallel to a top surface of the bottom electrode of the phase-change memory structure is 50 nm to 100 nm.

In some embodiments of the present disclosure, a width extending parallel to a top surface of the bottom electrode of the bottom electrode is larger than a width extending along the top surface of the bottom electrode of the phase-change memory structure.

In some embodiments of the present disclosure, the semiconductor device further includes a first insulating structure and a second insulating structure disposed on the bottom electrode. The phase-change memory structure is laterally sandwiched between the first insulating structure and the second insulating structure from a cross-sectional view of the semiconductor device.

In some embodiments of the present disclosure, the first insulating structure and the second insulating structure are respectively in contact with opposite sidewalls of the phase-change memory structure.

According to some embodiments of the present disclosure, a semiconductor device includes two electrodes, a plurality of phase-change memory structures, and an insulating structure. At least one of the two electrodes includes graphene. The phase-change memory structures are disposed between the two electrodes and in contact with different portions of at least one of the two electrodes. The insulating structure laterally surrounds each of the phase-change memory structures.

In some embodiments of the present disclosure, another of the two electrodes includes N-doped graphene.

In some embodiments of the present disclosure, each of the phase-change memory structures includes GeSbTe, SiGeSb, Sb₂Te₃, GeTe, Cr₂Ge₂Te₆, VO₂, MoO₂, V₂O₃, NbO₂, Fe₃O₄, FeS, Ta₂O₅, Ti₃O₅, Ti₂O₃, LaCoO₃, SmNiO₃, or combinations thereof.

In some embodiments of the present disclosure, a shape of a cross section of each of the phase-change memory structures is a regular hexagon.

In some embodiments of the present disclosure, a distance between any adjacent two of the phase-change memory structures is 50 nm to 100 nm.

In some embodiments of the present disclosure, each of the phase-change memory structures extends from an inner surface of one of the two top electrodes to an inner surface of another of the two electrodes, and a sidewall of each of the phase-change memory structures is straight.

According to the aforementioned embodiments of the present disclosure, the semiconductor device includes the bottom electrode, the top electrode, and at least one phase-change memory structure, and can be applied in the phase-change memory field. Since at least the bottom electrode for triggering the phase switching of the phase-change memory structure includes graphene, which has high carrier mobility, low resistance, excellent thermal conductivity, and flexible electronic properties, the power consumption can be reduced, and the charge transfer speed can be enhanced, thereby providing applicability for high-density semiconductor devices.

### BRIEF DESCRIPTION OF THE DRAWINGS

The disclosure can be more fully understood by reading the following detailed description of the embodiments, with reference made to the accompanying drawings as follows:

FIG. 1 is a schematic cross-sectional view of a semiconductor device according to some embodiments of the present disclosure;

FIG. 2 is the semiconductor device of FIG. 1 when initially being triggered by voltage pulse;

FIG. 3 is the semiconductor device of FIG. 1 when continuously being triggered by voltage pulse;

FIG. 4 is a schematic cross-sectional view of a semiconductor device according to some other embodiments of the present disclosure;

FIGS. 5A, 5B, and 5C are schematic cross-sectional views of the phase-change memory structures according to different embodiments of the present disclosure; and

FIGS. 6A and 6B are schematic cross-sectional views of the arrangement of the phase-change memory structures according to different embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

It should be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments.

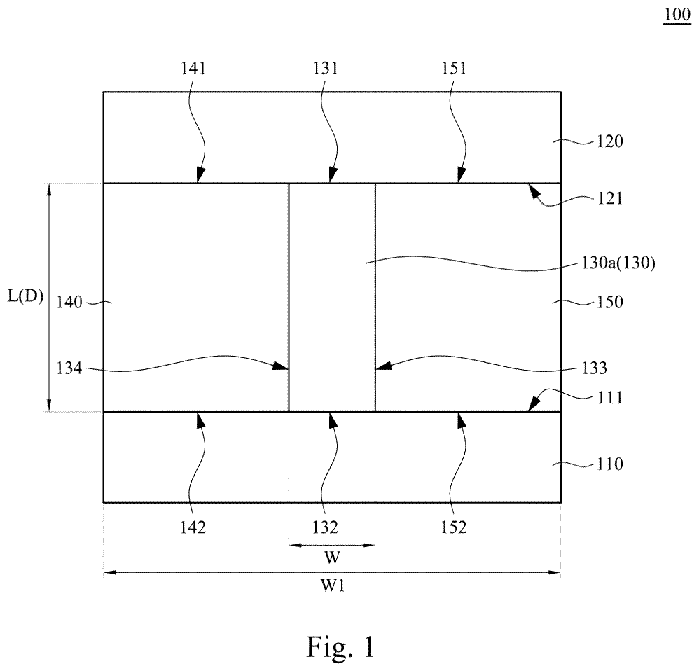

Furthermore, relative terms such as “lower” or “bottom” and “upper” or “top” can be used herein to describe the relationship between one element and another element, as shown in the figure. It should be understood that relative terms are intended to include different orientations of the device other than those shown in the figures. For example, if the device in one figure is turned over, elements described as being on the “lower” side of other elements will be oriented on the “upper” side of the other elements. Therefore, the exemplary term “lower” may include an orientation of “lower” and “upper,” depending on the specific orientation of the drawing. Similarly, if the device in one figure is turned over, elements described as “below” other elements will be oriented “above” the other elements. Therefore, the exemplary term “below” can include an orientation of “above” and “below. ” Reference is made to FIG. 1, which is a schematic cross-sectional view of a semiconductor device 100 according to some embodiments of the present disclosure. The semiconductor device 100 includes two electrodes (i.e., a bottom electrode 110 and a top electrode 120) and a phase-change memory structure 130. The top electrode 120 is disposed on the bottom electrode 110, and the phase-change memory structure 130 is disposed (sandwiched) between and in contact with the top electrode 120 and the bottom electrode 110. The semiconductor device 100 can be applied in a phase-change memory field, and can be, for, example, a memory device. During use, current is applied through the bottom electrode 110 and the top electrode 120. By controlling the intensity and duration of the voltage pulse, data storage and retrieval in semiconductor device 100 can be achieved. In detail, when the phase-change memory structure 130 is subjected to a low-power and long-duration voltage pulse, the material of the phase-change memory structure 130 crystallizes into a well-ordered lattice structure, forming a crystalline state with high electrical conductivity; when the phase-change memory structure 130 is subjected to a high-power and short-duration voltage pulse, atoms in the material of the phase-change memory structure 130 arrange randomly, forming an amorphous state with low electrical conductivity.

In the present disclosure, the bottom electrode 110 includes graphene. By selecting graphene as the material of the bottom electrode 110, the phase switching between the amorphous state and the crystalline state of the phase-change memory structure 130 can be well controlled, thereby greatly enhancing the read/write performance of the semiconductor device 100. As such, the semiconductor device 100 can be minimized to nanoscale, thereby improving the integration density of various electronic components of the semiconductor device 100. In detail, graphene's superior conductivity at the nanoscale is due to its ballistic transport properties, where electrons travel with minimal scattering, leading to very low electrical resistance. Its atomic-scale thickness and two-dimensional lattice structure provide an ideal path for electrons, reducing disruptions and energy loss. Also, strong carbon-carbon bonds and minimal defects further enhance its conductive pathways, allowing for efficient electron flow even at extremely small scales. These characteristics make graphene highly effective for applications requiring precise and efficient electrical conduction at the nanoscale.

In some embodiments, the top electrode 120 also includes graphene. In other words, the material of the bottom electrode 110 and the material of the top electrode 120 are the same. As such, the electrical efficacy brought by graphene can be further enhanced. In addition, by using the same material for both the top electrode 120 and the bottom electrode 110, the manufacturing process can be simplified by reducing variability, thus enhancing production yield and consistency. This uniformity also improves interface compatibility, minimizing defects and instability at the electrode-memory material junction, leading to better device performance. Also, it ensures symmetric electrical properties, enhancing read/write performance and reducing variability. In addition, matching thermal expansion coefficients between identical materials decreases stress from thermal cycling, boosting device stability and lifespan. Accordingly, the overall chemical stability is improved, as the risk of unwanted reactions or diffusion between different materials is minimized, promoting long-term reliability.

In some embodiments, the phase-change memory structure 130 may include germanium-antimony-tellurium alloy (e.g., GeSbTe), Sb₂Te₃, GeTe, Cr₂Ge₂Te₆, VO₂, MoO₂, V₂O₃, NbO₂, Fe₃O₄, FeS, Ta₂O₅, Ti₃O₅, Ti₂O₃, LaCoO₃, SmNiO₃, or combinations thereof. In some embodiments, each of the bottom electrode 110 and the top electrode 120 may include N-doped graphene, and the phase-change memory structure 130 may include GeSbTe. N-doped graphene offer significant advantages when used with GeSbTe. Firstly, it enhances electrical conductivity, improving charge transfer efficiency, and enabling faster switching speeds with lower power consumption. Secondly, it provides enhanced stability, maintaining GeSbTe integrity during phase changes due to better thermal and chemical resilience. Thirdly, it reduces contact resistance, minimizing energy losses at the electrode-memory material interface and enhancing memory cell efficiency. Additionally, N-doped graphene ensures a uniform interface with GeSbTe, promoting consistent switching behavior across memory cells. Furthermore, its high temperature tolerance further supports reliable performance in elevated temperature environments, and also extends the device's operational life by mitigating degradation at the electrode-memory material interface. Overall, these qualities underscore N-doped graphene as a suitable material for optimizing the performance, efficiency, and longevity of the GeSbTe-based memory device (semiconductor device 100).

Overall, compared with conventional electrode materials such as silver, copper, etc., through the combination of the N-doped graphene electrode and the GeSbTe phase-change memory structure 130, the power consumption of the semiconductor device 100 can be greatly reduced, and the charge transfer speed can be greatly enhanced, thereby providing applicability for high-density semiconductor devices.

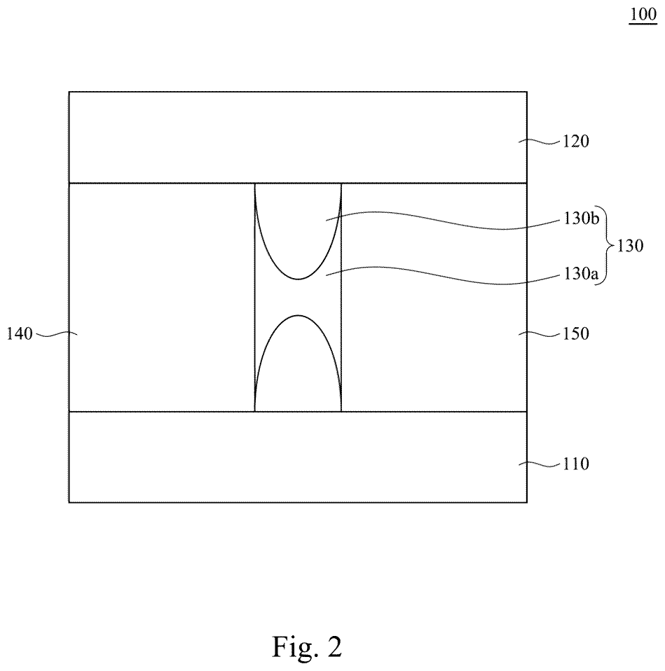

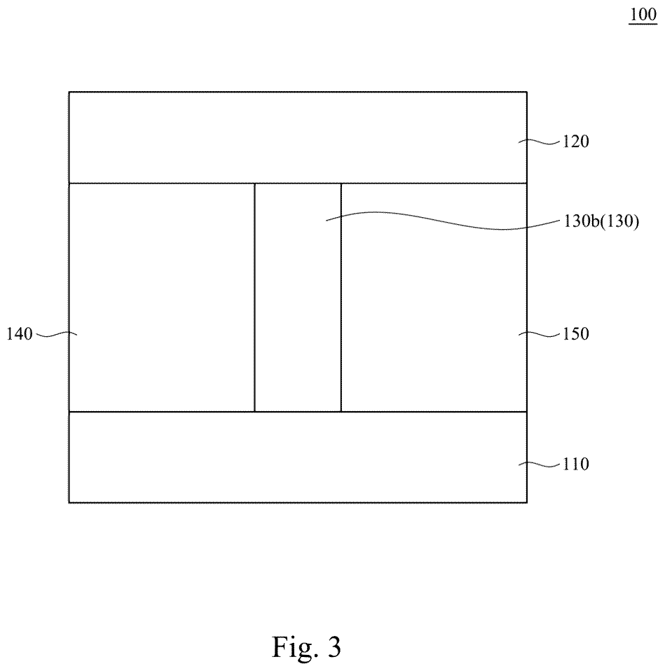

Reference is made to FIGS. 2-3, in which FIG. 2 is the semiconductor device 100 of FIG. 1 when initially being triggered by voltage pulse, and FIG. 3 is the semiconductor device 100 of FIG. 1 when continuously being triggered by voltage pulse. In detail, the material of the phase-change memory structure 130 may initially be well-ordered to form a lattice structure (crystal crystalline state) 130a (see FIG. 1), and when the phase-change memory structure 130 is subjected to a high-power and short-duration pulse, atoms near the bottom electrode 110 and the top electrode 120 in the material of the phase-change memory structure 130 starts to arrange randomly, forming an amorphous state 130b with low electrical conductivity (see FIG. 2). Further, when the phase-change memory structure 130 is continuously subjected to the high-power and short-duration pulse, the entire phase-change memory structure 130 turns into the amorphous state 130b (see FIG. 3). Since the charge transfer speed is greatly enhanced through the combination of the (N-doped) graphene electrode and the GeSbTe phase-change memory structure 130, the phase-switching (phase-change) time of the phase-change memory structure 130 from the crystalline state to the amorphous state (or from the amorphous state to the crystalline state) can range from millisecond to sub-nanosecond, thereby greatly reducing the power consumption.

Reference is made back to FIG. 1. In some embodiments, the phase-change memory structure 130 can be minimized to nanoscale. For example, the phase-change memory structure 130 can extend from a bottom surface 121 (an inner surface) of the top electrode 120 to a top surface 111 (an inner surface) of the bottom electrode 110, in which a length L extending from the top electrode 120 to the bottom electrode 110 of the phase-change memory structure 130 (i.e., a distance D from the bottom surface 121 of the top electrode 120 to the top surface 111 of the bottom electrode 110) is 100 nm to 200 nm (e.g., 110 nm, 120 nm, 130 nm, 140 nm, 150 nm, 160 nm, 170 nm, 180 nm, 190 nm), and a width W, which is in a direction perpendicular to the direction of length L, of the phase-change memory structure 130 (the width W extending parallel to the top surface 111 of the bottom electrode 110 of the phase-change memory structure 130) is 50 nm to 100 nm (e.g., 60 nm, 70 nm, 80 nm, 90 nm). Since the phase-change memory structure 130 of the present disclosure can be scaled down to nanoscale, is provide several advantages such as increased speed due to shorter electronic paths, reduced power consumption, higher storage density, lower production costs, improved heat management, and more opportunities for innovative designs. These advantages result in faster, more efficient, and cost-effective memory technologies.

In addition, since the width W of the phase-change memory structure 130 is small, the contact area between the phase-change memory structure 130 and the electrode (i.e., the top electrode 120 and the bottom electrode 110) can be minimized. In this way, the energy required for read/write operations can be reduced by concentrating heat in a smaller region, and the read/write speed can be enhanced by inducing phase change (phase switching) more rapidly. Also, the thermal control can be improved by limiting heat diffusion, the leakage current can be decreased, and the durability of the phase-change memory structure 130 can be increased by reducing thermal stress and material degradation.

In some embodiments, the semiconductor device 100 further includes a first insulating structure 140 and a second insulating structure 150 disposed on the bottom electrode 110, in which the phase-change memory structure 130 is laterally sandwiched between the first insulating structure 140 and the second insulating structure 150 from a side cross-sectional view (the view of FIG. 1) of the semiconductor device. In some embodiments, the first insulating structure 140 and the second insulating structure 150 are disposed (sandwiched) between and in contact with the top electrode 120 and the bottom electrode 110. In some embodiments, a top surface 131 of the phase-change memory structure 130, a top surface 141 of the first insulating structure 140, and a top surface 151 of the second insulating structure 150 are coplanar and in contact with the top electrode 120; similarly, a bottom surface 132 of the phase-change memory structure 130, a bottom surface 142 of the first insulating structure 140, and a bottom surface 152 of the second insulating structure 150 are coplanar and in contact with the bottom electrode 110. As such, the phase-change memory structure 130, the first insulating structure 140, and second insulating structure 150 share the same length (i.e., Length L), which can improve the durability of the semiconductor device 100.

The first insulating structure 140 and the second insulating structure 150 can protect the phase-change memory structure 130 from electrical leakage, thereby ensuring data integrity, and can confine heat within the phase-change area, thereby enhancing thermal efficiency and reducing the energy required for phase switching. Also, the first insulating structure 140 and the second insulating structure 150 can protect the semiconductor device 100 from external interference and damage, thereby increasing its durability, and can maintain the stability and performance of the semiconductor device 100 by preventing unwanted chemical reactions and diffusion of elements. In some embodiments, the first insulating structure 140 and the second insulating structure 150 may include materials such as Al₂O₃, ZrO₂ or combinations thereof, thereby better achieving the above efficacies. In some embodiments, the first insulating structure 140 and the second insulating structure 150 are respectively in contact with the opposite sidewalls (i.e., the entire first sidewall 133 and the entire second sidewall 134) of the phase-change memory structure 130, leaving no gap between the insulating structures (i.e., the first insulating structure 140 and the second insulating structure 150) and the phase-change memory structure 130. In this way, the first insulating structure 140 and the second insulating structure 150 can provide better protection to the phase-change memory structure 130.

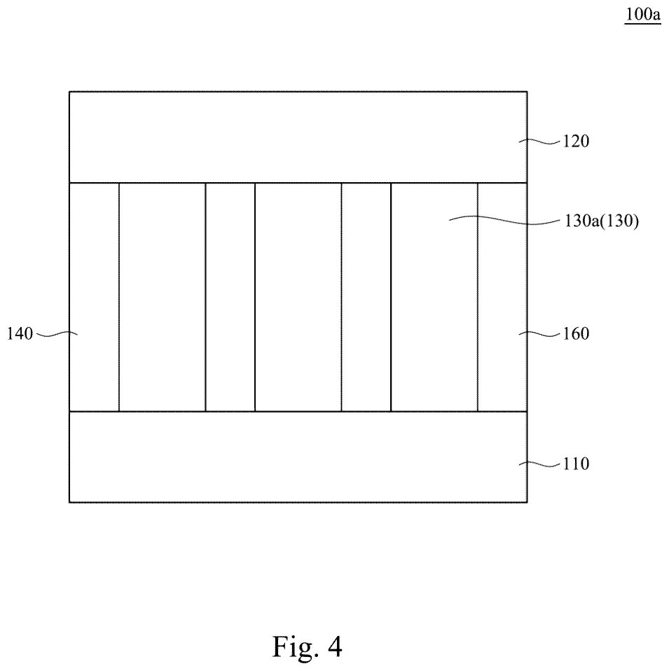

In some embodiments, a width W1 extending parallel to the top surface 111 of the bottom electrode 110 of the bottom electrode 110 is larger than the width W extending parallel to the top surface 111 of the bottom electrode 110 of the phase-change memory structure 130. In this way, more than one phase-change memory structure 130 can be disposed on the bottom electrode 110, which is beneficial for improving the integration density of various electronic components of the semiconductor device 100. More specifically, reference is made to FIG. 4, which is a schematic cross-sectional view of a semiconductor device 100a according to some other embodiments of the present disclosure. A difference between the semiconductor device 100a and the semiconductor device 100 is that the semiconductor device 100a includes a plurality of phase-change memory structures 130 disposed between the top electrode 120 and the bottom electrode 110 and in contact with different portions of the bottom electrode 110 (top electrode 120), and that an insulating structure 160 is disposed on the bottom electrode 110 and laterally and tightly surrounds each of the phase-change memory structures 130. It should be understood that, in addition to the number of the phase-change memory structures 130, other features (e.g., materials) and configuration of the phase-change memory structure 130 and the insulating structure 160 can respectively refer to the phase-change memory structure 130 and the first and second insulating structures 140 and 150 mentioned above, and will not be repeated hereinafter.

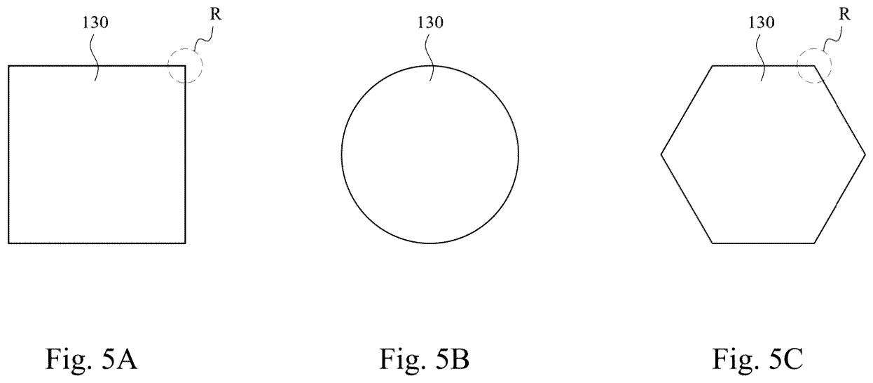

Reference is made to FIGS. 5A, 5B, and 5C, which are schematic cross-sectional views of the phase-change memory structures 130 according to different embodiments of the present disclosure. In detail, the cross sections shown in FIGS. 5A, 5B, and 5C are cross sections taken along the direction of the width W of the phase-change memory structures 130. In other words, the cross sections shown in FIGS. 5A, 5B, and 5C can be seen as top views of the phase-change memory structures 130. As shown in FIGS. 5A, 5B, and 5C, a shape of the cross section of the phase-change memory structure 130 can be a square, a circle, or a regular hexagon. Since a sidewall (e.g., a first sidewall 133 or a second sidewall 134, see FIG. 1) of the phase-change memory structure 130 is straight, the phase-change memory structure 130 can be a prism or a cylinder. These shapes give convenience for manufacturing. In some preferred embodiments, the shape of the cross section of the phase-change memory structure 130 is a regular hexagon. Such a shape can provide an even higher arrangement density for the of the phase-change memory structure 130.

Also, it is understood that, when the shape of the cross section of the phase-change memory structure 130 is a square, the width W of the phase-change memory structure 130 is the diagonal length of the square; when the shape of the cross section of the phase-change memory structure 130 is a circle, the width W of the phase-change memory structure 130 is the diameter of the square; when the shape of the cross section of the phase-change memory structure 130 is a regular hexagon, the width W of the phase-change memory structure 130 is the diagonal length of the regular hexagon. In some embodiments, the corner R of the phase-change memory structure 130 can be a sharp corner for convenience of manufacturing. In some preferred embodiments, the corner R of the phase-change memory structure 130 can be a rounded corner for managing heat accumulation. In detail, rounded corners can distribute heat more evenly, reduce stress, and improve thermal stability, which enhances the device's performance and longevity.

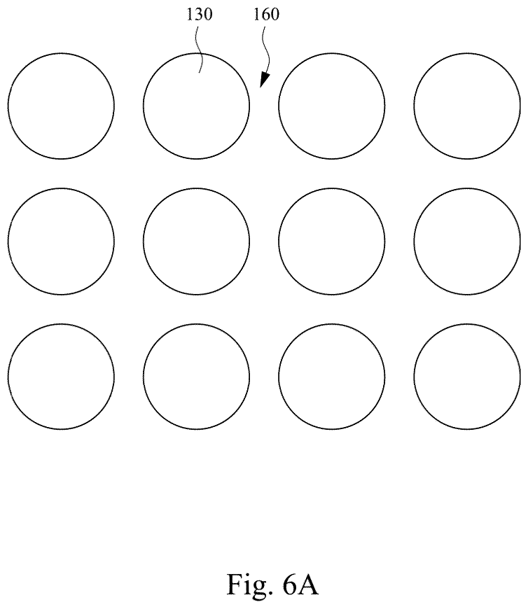

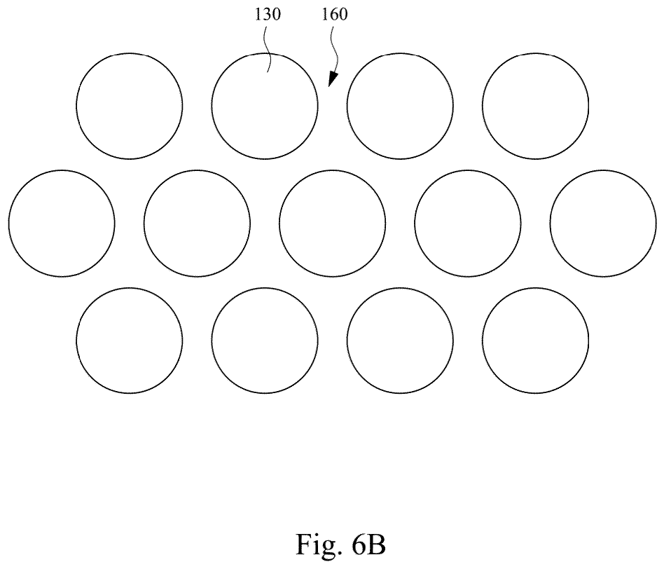

Reference is made to FIGS. 6A and 6B, which are schematic cross-sectional views of the arrangement of the phase-change memory structures 130 according to different embodiments of the present disclosure. In some embodiments, the phase-change memory structures 130 can be arranged at intervals. As shown in FIG. 6A, in some embodiments, the phase-change memory structures 130 can be arranged in an array. An array arrangement improves scalability, enabling higher storage density. Also, an array arrangement enhances performance through parallel processing, improves reliability with error correction, and manages heat more effectively. As shown in FIG. 6B, in some other embodiments, the phase-change memory structures 130 can be arranged in a staggered-manner. A staggered arrangement improves thermal management by dissipating heat better and reducing crosstalk between the phase-change memory structures 130, thus enhancing reliability and extending the lifespan of the phase-change memory structures 130.

In some embodiments, a distance between any adjacent two of the phase-change memory structures 130 is 50 nm to 100 nm (e.g., 60 nm, 70 nm, 80 nm, 90 nm). The “distance” herein refers to the minimum value of the distance from a sidewall of one phase-change memory structure 130 to a sidewall of the adjacent phase-change memory structure 130. A large distance between the phase-change memory structures 130 can lead to challenges in achieving precise and uniform heating during phase transitions. This can result in variability in the crystallization or amorphization processes across different phase-change memory structures 130, leading to inconsistencies in data storage and retrieval. In contrast, if the distance between the phase-change memory structures 130 is too small, it may limit the heat dissipation between the phase-change memory structures 130, causing localized overheating and potentially premature wear or degradation of the material. Therefore, maintaining an optimal distance between the phase-change memory structures 130 is crucial for ensuring consistent and reliable phase-change behavior, and also essential for the efficient operation and durability of phase-change memory technologies.

According to the aforementioned embodiments of the present disclosure, the semiconductor device can be applied in a phase-change memory field, and can be, for, example, a memory device. The semiconductor device includes the bottom electrode, the top electrode, and at least one phase-change memory structure, and can be applied in the phase-change memory field. Since at least the bottom electrode for triggering the phase switching of the phase-change memory structure includes graphene, which has high carrier mobility, low resistance, excellent thermal conductivity, and flexible electronic properties, the power consumption can be reduced, and the charge transfer speed can be enhanced, thereby providing applicability for high-density semiconductor devices.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

What is claimed is:

1. A semiconductor device, comprising:
a bottom electrode comprising graphene;
a top electrode disposed on the bottom electrode; and
a phase-change memory structure disposed between the top electrode and the bottom electrode.

2. The semiconductor device of claim 1, wherein the top electrode comprises graphene.

3. The semiconductor device of claim 2, wherein each of the bottom electrode and the top electrode comprises N-doped graphene.

4. The semiconductor device of claim 1, wherein the phase-change memory structure comprises GeSbTe, SiGeSb, Sb₂Te₃, GeTe, Cr₂Ge₂Te₆, VO₂, MoO₂, V₂O₃, NbO₂, Fe₃O₄, FeS, Ta₂O₅, Ti₃O₅, Ti₂O₃, LaCoO₃, SmNiO₃, or combinations thereof.

5. The semiconductor device of claim 1, wherein a length extending from the top electrode to the bottom electrode of the phase-change memory structure is 100 nm to 200 nm.

6. The semiconductor device of claim 1, wherein a width extending parallel to a top surface of the bottom electrode of the phase-change memory structure is 50 nm to 100 nm.

7. The semiconductor device of claim 1, wherein a width extending parallel to a top surface of the bottom electrode of the bottom electrode is larger than a width extending along the top surface of the bottom electrode of the phase-change memory structure.

8. The semiconductor device of claim 1, further comprising:
a first insulating structure and a second insulating structure disposed on the bottom electrode, wherein the phase-change memory structure is laterally sandwiched between the first insulating structure and the second insulating structure from a cross-sectional view of the semiconductor device.

9. The semiconductor device of claim 8, wherein the first insulating structure and the second insulating structure are respectively in contact with opposite sidewalls of the phase-change memory structure.

10. A semiconductor device, comprising:
two electrodes, wherein at least one of the two electrodes comprises graphene;
a plurality of phase-change memory structures disposed between the two electrodes and in contact with different portions of at least one of the two electrodes; and
an insulating structure laterally surrounding each of the phase-change memory structures.

11. The semiconductor device of claim 10, wherein another of the two electrodes comprises N-doped graphene.

12. The semiconductor device of claim 10, wherein each of the phase-change memory structures comprises GeSbTe, SiGeSb, Sb₂Te₃, GeTe, Cr₂Ge₂Te₆, VO₂, MoO₂, V₂O₃, NbO₂, Fe₃O₄, FeS, Ta₂O₅, Ti₃O₅, Ti₂O₃, LaCoO₃, SmNiO₃, or combinations thereof.

13. The semiconductor device of claim 9, wherein a shape of a cross section of each of the phase-change memory structures is a regular hexagon.

14. The semiconductor device of claim 9, wherein a distance between any adjacent two of the phase-change memory structures is 50 nm to 100 nm.

15. The semiconductor device of claim 9, wherein each of the phase-change memory structures extends from an inner surface of one of the two electrodes to an inner surface of another of the two electrodes, and a sidewall of each of the phase-change memory structures is straight.
